(19) United States
(12) Patent Application Publication
(10) Pub. No.: US 2016/0155959 A1
(43) Pub. Date: Jun. 2, 2016

(54) Organic Electroluminescent Device

(71) Applicant: MERCK PATENT GMBH, Darmstadt (DE)

(72) Inventors: Joachim Kaiser, Darmstadt (DE); Christof Pflumm, Darmstadt (DE); Amir Hossain Parham, Frankfurt Am Main (DE); Thomas Eberle, Landau (DE); Philipp Stoessel, Frankfurt Am Main (DE); Jonas Valentin Kroeber, Frankfurt Am Main (DE); Anja Jatsch, Frankfurt Am Main (DE); Heinrich Becker, Ober-Ramstadt (DE); Rouven Linge, Darmstadt (DE)

(73) Assignee: Merck Patent GmbH, Darmstadt (DE)

(21) Appl. No.: 14/902,066

(22) PCT Filed: Jun. 11, 2014
(86) PCT No.: PCT/EP2014/001586

§ 371 Date: Dec. 30, 2015

(30) Foreign Application Priority Data
Jul. 2, 2013 (EP) 13003342.6

(51) Int. Cl. H01L 51/00; C09K 11/02; C09K 11/06

(52) U.S. Cl. CPC H01L 51/0085; H01L 51/0067; H01L 51/0072; H01L 51/0074; H01L 51/0056; C09K 11/06; C09K 11/025; H01L 51/504

(57) ABSTRACT

The present invention relates to organic electroluminescent devices which comprise a mixture of an iridium complex and a triazine or pyrimidine compound in the emitting layer.

The present invention relates to organic electroluminescent devices which comprise a mixture of an iridium complex and a triazine or pyrimidine compound in the emitting layer.

The structure of organic electroluminescent devices (OLEDs) in which organic semiconductors are employed as functional materials is described, for example, in U.S. Pat. No. 4,539,507, U.S. Pat. No. 5,151,629, EP 0676461 and WO 98/27136. The emitting materials employed here are increasingly organometallic complexes which exhibit phosphorescence instead of fluorescence (M. A. Baldo et al., Appl. Phys. Lett. 1999, 75, 4-6). For quantum-mechanical reasons, an up to four-fold increase in the energy and power efficiency is possible using organometallic compounds as phosphorescence emitters.

The properties of phosphorescent OLEDs are determined not only by the triplet emitters employed. The other materials used, in particular also the matrix materials, are also of particular importance here. Improvements in these materials or, in particular, also the combination of triplet emitter and matrix material may thus also result in significant improvements in the OLED properties.

In particular, there is still a need for improvement in the operating lifetime of phosphorescent yellow OLEDs and OLEDs which combine yellow emission with another colour in order, for example, to obtain white light. This applies, in particular, with respect to TV applications based on white+coloured filter technology, since the use of the coloured filter here means that a significant part of the emitted light is absorbed and the basic yellow or white OLED has to be operated with increased brightness, which translates into an increased demand with respect to the operating lifetime. This likewise applies to lighting applications, since the trend here is away from the 1000 cd/m² light tiles that were demonstrated in past years to ever-higher luminous densities in the region of up to 5000 cd/m².

The technical object on which the present invention is based is thus the provision of OLEDs having an improved lifetime, in particular of yellow- and white-emitting OLEDs.

Surprisingly, it has been found that organic electroluminescent devices which comprise an iridium complex having optionally substituted benzoquinoline ligands and a triazine or pyrimidine compound in the emitting layer achieve this object and result in excellent lifetimes in the region of up to 1 million hours. The lifetime is thus a factor of up to 3 to 5 better compared with other matrix materials.

Benzoquinoline in the sense of the present invention has the following structure:

Iridium complexes having benzoquinoline ligands are known, for example, from EP 1353388, EP 1267428 or US 2001/0019782. The use of these complexes in combination with triazine or pyrimidine ligands has neither been disclosed nor suggested. In particular, an increase in the lifetime as in the present case has neither been obtained with another matrix, nor would a lifetime increase of this type have been predictable from the prior art.

The present invention thus relates to organic electroluminescent devices comprising a mixture of this type.

The invention thus relates to an organic electroluminescent device comprising a mixture of an iridium complex which contains at least one optionally substituted benzoquinoline ligand and a triazine or pyrimidine derivative which has a molecular weight of at least 350 g/mol, preferably at least 400 g/mol, in the emitting layer.

The triazine or pyrimidine derivative is described in greater detail below:

The triazine derivative is preferably a compound of the following formula (1) and the pyrimidine derivative is preferably a compound of the following formula (2),

where the following applies to the symbols used:
R is selected on each occurrence, identically or differently, from the group consisting of H, D, F, CN, N(Ar)₂, N(R¹)₂, C(═O)Ar, C(═O)R¹, P(═O)(Ar)₂, a straight-chain alkyl, alkoxy or thioalkyl group having 1 to 40 C atoms or a branched or cyclic alkyl, alkoxy or thioalkyl group having 3 to 40 C atoms or an alkenyl or alkynyl group having 2 to 40 C atoms, each of which may be substituted by one or more radicals R¹, where one or more non-adjacent CH₂ groups may be replaced by R¹C═CR¹, C≡C, Si(R¹)₂, C═O, C═S, C═NR¹, P(═O)(R¹), SO, SO₂, NR¹, O, S or CONR¹ and where one or more H atoms may be replaced by D, F, Cl, Br, I, CN or NO₂, an aromatic or heteroaromatic ring system having 5 to 80, preferably 5 to 60, aromatic ring atoms, which may in each case be substituted by one or more radicals R¹, an aryloxy or heteroaryloxy group having 5 to 60 aromatic ring atoms, which may be substituted by one or more radicals R¹, or an aralkyl or heteroaralkyl group having 5 to 60 aromatic ring atoms, which may be substituted by one or more radicals R¹, where two or more adjacent substituents R may optionally form a monocyclic or polycyclic, aliphatic, aromatic or heteroaromatic ring system, which may be substituted by one or more radicals R¹;
   with the proviso that at least one group R stands for an aromatic or heteroaromatic ring system in accordance with the above definition;
R¹ is selected on each occurrence, identically or differently, from the group consisting of H, D, F, Cl, Br, I, CN, NO₂, N(Ar)₂, N(R²)₂, C(═O)Ar, C(═O)R², P(═O)(Ar)₂, a straight-chain alkyl, alkoxy or thioalkyl group having 1 to 40 C atoms or a branched or cyclic alkyl, alkoxy or thioalkyl group having 3 to 40 C atoms or an alkenyl or alkynyl group having 2 to 40 C atoms, each of which may be substituted by one or more radicals R², where one or more non-adjacent CH₂ groups may be replaced by R²C═CR², C≡C, Si(R²)₂, C═O, C═S, C═NR², P(═O)(R²), SO, SO₂, NR², O, S or CONR² and where one or more H atoms may be replaced by D, F, Cl, Br, I, CN or NO₂, an aromatic or heteroaromatic ring system having 5 to 60 aromatic ring atoms, which may in each case be substituted by one or more radicals R², an aryloxy or heteroaryloxy group having 5 to 60 aromatic ring atoms, which may be substituted by one or more radicals R², or an aralkyl or heteroaralkyl group having 5 to 60 aromatic ring atoms, where two or more adjacent substituents R¹ may optionally form a monocyclic or polycyclic, aliphatic, aromatic or heteroaromatic ring system, which may be substituted by one or more radicals R²;
Ar is on each occurrence, identically or differently, an aromatic or heteroaromatic ring system having 5-30 aromatic ring atoms, which may be substituted by one or more non-aromatic radicals R²; two radicals Ar here which are bonded to the same N atom or P atom may also be bridged to one another by a single bond or a bridge selected from N(R²), C(R²)₂, O or S;
R² is selected from the group consisting of H, D, F, CN, an aliphatic hydrocarbon radical having 1 to 20 C atoms, an aromatic or heteroaromatic ring system having 5 to 30 aromatic ring atoms, in which one or more H atoms may be replaced by D, F, Cl, Br, I or CN, where two or more adjacent substituents R² may form a mono- or polycyclic, aliphatic, aromatic or heteroaromatic ring system with one another.

An aryl group in the sense of this invention contains 6 to 60 C atoms; a heteroaryl group in the sense of this invention contains 2 to 60 C atoms and at least one heteroatom, with the proviso that the sum of C atoms and heteroatoms is at least 5. The heteroatoms are preferably selected from N, O and/or S. An aryl group or heteroaryl group here is taken to mean either a simple aromatic ring, i.e. benzene, or a simple heteroaromatic ring, for example pyridine, pyrimidine, thiophene, etc., or a condensed (anellated) aryl or heteroaryl group, for example naphthalene, anthracene, phenanthrene, quinoline, isoquinoline, etc. Aromatic groups which are linked to one another by a single bond, such as, for example, biphenyl, are, by contrast, not referred to as aryl or heteroaryl group, but instead as aromatic ring system.

An aromatic ring system in the sense of this invention contains 6 to 80 C atoms and no aromatic heteroatoms in the ring system. A heteroaromatic ring system in the sense of this invention contains 2 to 60 C atoms and at least one heteroatom in the ring system, with the proviso that the sum of C atoms and heteroatoms is at least 5. The heteroatoms are preferably selected from N, O and/or S. The heteroaromatic ring system here contains one, two, three, four or five heteroatoms. For the purposes of this invention, an aromatic or heteroaromatic ring system is intended to be taken to mean a system which does not necessarily contain only aryl or heteroaryl groups, but instead in which, in addition, a plurality of aryl or heteroaryl groups may be connected by a non-aromatic unit, such as, for example, a C, N or O atom. Thus, for example, systems such as fluorene, 9,9′-spirobifluorene, 9,9-diaryifluorene, triarylamine, diaryl ether, stilbene, etc., are also intended to be taken to be aromatic ring systems for the purposes of this invention, as are systems in which two or more aryl groups are connected, for example, by a short alkyl group.

For the purposes of the present invention, an aliphatic hydrocarbon radical or an alkyl group or an alkenyl or alkynyl group, which may contain 1 to 40 C atoms and in which, in addition, individual H atoms or CH₂ groups may be substituted by the above-mentioned groups, is preferably taken to mean the radicals methyl, ethyl, n-propyl, i-propyl, n-butyl, i-butyl, s-butyl, t-butyl, 2-methylbutyl, n-pentyl, s-pentyl, neopentyl, cyclopentyl, n-hexyl, neohexyl, cyclohexyl, n-heptyl, cycloheptyl, n-octyl, cyclooctyl, 2-ethylhexyl, trifluoromethyl, pentafluoroethyl, 2,2,2-trifluoroethyl, ethenyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl, heptynyl or octynyl. An alkoxy group having 1 to 40 C atoms is preferably taken to mean methoxy, trifluoromethoxy, ethoxy, n-propoxy, i-propoxy, n-butoxy, i-butoxy, s-butoxy, t-butoxy, n-pentoxy, s-pentoxy, 2-methylbutoxy, n-hexoxy, cyclohexyloxy, n-heptoxy, cycloheptyloxy, n-octyloxy, cyclooctyloxy, 2-ethylhexyloxy, pentafluoroethoxy and 2,2,2-trifluoroethoxy. A thioalkyl group having 1 to 40 C atoms is taken to mean, in particular, methylthio, ethylthio, n-propylthio, i-propylthio, n-butylthio, i-butylthio, s-butylthio, t-butylthio, n-pentylthio, s-pentylthio, n-hexylthio, cyclohexylthio, n-heptyithio, cycloheptylthio, n-octytthio, cyclooctylthio, 2-ethylhexytthio, trifluoromethylthio, pentafluoroethylthio, 2,2,2-trifluoroethylthio, ethenylthio, propenylthio, butenylthio, pentenylthio, cyclopentenythio, hexenylthio, cyclohexenylthio, heptenylthio, cycloheptenylthio, octenylthio, cyclooctenylthio, ethynylthio, propynylthio, butynylthio, pentynylthio, hexynylthio, heptynylthio or octynylthio. In general, alkyl, alkoxy or thioalkyl groups in accordance with the present invention may be straight-chain, branched or cyclic, where one or more non-adjacent CH₂ groups may be replaced by the above-mentioned groups; furthermore, one or more H atoms may also be replaced by D, F, Cl, Br, I, CN or NO₂, preferably F, CI or CN, further preferably F or CN, particularly preferably CN.

An aromatic or heteroaromatic ring system having 5-30 or 5-60 aromatic ring atoms respectively, which may also in each case be substituted by the above-mentioned radicals R, R¹ or R², is taken to mean, in particular, groups derived from benzene, naphthalene, anthracene, benzanthracene, phenanthrene, pyrene, chrysene, perylene, fluoranthene, naphthacene, pentacene, benzopyrene, biphenyl, biphenylene, terphenyl, triphenylene, fluorene, spirobifluorene, dihydrophenanthrene, dihydropyrene, tetrahydropyrene, cis- or trans-indenofluorene, cis- or trans-indenocarbazole, cis- or trans-indolocarbazole, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, hexaazatriphenylene, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubin, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole or groups derived from a combination of these systems.

In compounds of the formula (1) or formula (2), at least one of the substituents R stands, as described above, for an aromatic or heteroaromatic ring system. In formula (1), it is preferred for all three substituents R to stand for an aromatic or heteroaromatic ring system, which may in each case be substituted by one or more radicals R¹. In formula (2), it is particularly preferred for one, two or three substituents R to stand for an aromatic or heteroaromatic ring system, which may in each case be substituted by one or more radicals R¹, and for the other substituents R to stand for H. Particularly preferred embodiments are the compounds of the following formulae (1) and (2a) to (2d),

where R stands, identically or differently, for an aromatic or heteroaromatic ring system having 5 to 80 aromatic ring atoms, preferably 5 to 60 aromatic ring atoms, which may in each case be substituted by one or more radicals R¹, and R¹ has the meaning given above.

Of the compounds of the formula (2), the compounds of the formulae (2b) and (2d) are particularly preferred, in particular the compounds of the formula (2d).

Preferred aromatic or heteroaromatic ring systems contain 5 to 30 aromatic ring atoms, in particular 6 to 24 aromatic ring atoms, and may be substituted by one or more radicals R¹. The aromatic or heteroaromatic ring systems here preferably contain no condensed aryl or heteroaryl groups in which more than two aromatic six-membered rings are condensed directly onto one another. They particularly preferably contain absolutely no aryl or heteroaryl groups in which aromatic six-membered rings are condensed directly onto one another. This preference is due to the higher triplet energy of substituents of this type. Thus, it is preferred for R to contain, for example, no naphthyl groups or higher condensed aryl groups and likewise no quinoline groups, acridine groups, etc. By contrast, it is possible for R to contain, for example, fluorene groups, carbazole groups, dibenzofuran groups, etc., since no 6-membered aromatic or heteroaromatic rings in these structures are condensed directly onto one another.

Preferred substituents R are selected from the group consisting of benzene, ortho-, meta- or para-biphenyl, ortho-, meta-, para- or branched terphenyl, ortho-, meta-, para- or branched quaterphenyl, 1-, 2-, 3- or 4-fluorenyl, 1-, 2-, 3- or 4-spirobifluorenyl, 1- or 2-naphthyl, pyrrole, furan, thiophene, indole, benzofuran, benzothiophene, 1-, 2- or 3-carbazole, 1-, 2- or 3-dibenzofuran, 1-, 2- or 3-dibenzothiophene, indenocarbazole, indolocarbazole, 2-, 3- or 4-pyridine, 2-, 4- or 5-pyrimidine, pyrazine, pyridazine, triazine, phenanthrene, triphenylene or combinations of two or three of these groups, each of which may be substituted by one or more radicals R¹.

It is especially preferred for at least one group R to be selected from the structures of the following formulae (3) to (29),

where R¹ and R² have the above-mentioned meanings, the dashed bond represents the bond to the triazine unit in formula (1) or to the pyrimidine unit in formula (2), and furthermore:
X is on each occurrence, identically or differently, CR¹ or N, where preferably a maximum of 2 symbols X per ring stand for N;
Y is on each occurrence, identically or differently, C(R¹)₂, NR¹, O, S or BR¹;
n is 0 or 1, where n equals 0 means that no group Y is bonded at this position and instead radicals R¹ are bonded to the corresponding carbon atoms.

In preferred groups of the above-mentioned formulae (3) to (29), a maximum of one symbol X per ring stands for N. The symbol X particularly preferably stands, identically or differently on each occurrence, for CR¹, in particular for CH.

Preferred groups Y are selected, identically or differently on each occurrence, from NR¹, C(R¹)₂ or O.

If the groups of the formulae (3) to (29) contain a plurality of groups Y, all combinations from the definition of Y are suitable for this purpose. Preference is given to groups of the formulae (3) to (29) in which one group Y stands for NR¹ and the other group Y stands for C(R¹)₂ or in which both groups Y stand for NR¹ or in which both groups Y stand for O. In the groups of the formulae (21) to (24), preferably one group Y stands for NR¹ and the other groups Y stand for C(R¹)₂.

In a further preferred embodiment of the invention, at least one group Y in the formulae (3) to (29) stands, identically or differently on each occurrence, for C(R¹)₂ or for NR¹.

Furthermore preferably, the substituent R¹ which is bonded directly to a nitrogen atom in these groups stands for an aromatic or heteroaromatic ring system having 5 to 24 aromatic ring atoms, which may also be substituted by one or more radicals R². In a particularly preferred embodiment, this substituent R¹ stands, identically or differently on each occurrence, for an aromatic or heteroaromatic ring system having 6 to 24 aromatic ring atoms, which contains no condensed aryl groups and which contains no condensed heteroaryl groups in which two or more aromatic or heteroaromatic 6-membered ring groups are condensed directly onto one another and which may in each case also be substituted by one or more radicals R².

If Y stands for C(R¹)₂, R¹ preferably stands, identically or differently on each occurrence, for a linear alkyl group having 1 to 10 C atoms or for a branched or cyclic alkyl group having 3 to 10 C atoms or for an aromatic or heteroaromatic ring system having 5 to 24 aromatic ring atoms, which may also be substituted by one or more radicals R². R¹ very particularly preferably stands for a methyl group or for a phenyl group. The two groups R¹ which are bonded to the same carbon atom here may also form a ring with one another and thus form a spiro system, which may be substituted by one or more radicals R². In a preferred embodiment of the invention, both groups R¹ stand for phenyl groups, which are linked to one another and thus form a spiro system and which may optionally be substituted by one or more radicals R². Thus, a spirobifluorene is formed, for example, from the structures of the formulae (4) to (7).

It may furthermore be preferred for the group of the above-mentioned formulae (3) to (29) not to bond directly to the triazine in formula (1) or the pyrimidine in formula (2), but instead via a bridging group V. This bridging group V is then preferably selected from an aromatic or heteroaromatic ring system having 5 to 24 aromatic ring atoms, in particular having 6 to 12 aromatic ring atoms, which may in each case be substituted by one or more radicals R¹. Particularly suitable are, for example, ortho-, meta- or para-phenylene groups, each of which may be substituted by one or more radicals R¹.

The groups R in formulae (1) and (2a) to (2d) which do not stand for a group of one of the formulae (3) to (29) preferably stand for an aromatic ring system having 6 to 24 aromatic C atoms, which may be substituted by one or more radicals R¹. The aromatic ring system here preferably contains no aryl groups in which more than two six-membered rings are condensed directly onto one another. The aromatic ring system particularly preferably contains absolutely no condensed aryl groups.

The above-mentioned embodiments can be combined with one another as desired. The above-mentioned preferences preferably occur simultaneously.

Examples of preferred compounds of the formula (1) or (2) are the following compounds.

Preferred embodiments of the iridium complex having optionally substituted benzoquinoline as ligand are described below.

The iridium complex is preferably a compound of the following formula (30),

Ir(L)ₘ(L′)ₒ formula (30)

where Ir(L)ₘ stands for a structure of the following formula (31),

where R has the above-mentioned meanings, but adjacent radicals R cannot form an aromatic ring system, and furthermore:
L′ is, identically or differently on each occurrence, a bidentate monoanionic ligand;
m is 1, 2 or 3;
o is 3-m.

In a preferred embodiment of the invention, the unit of the formula M(L)ₘ is selected from the structures of the following formula (31a),

where the symbols and indices used have the above-mentioned meanings.

In a further preferred embodiment of the invention, m=2 or 3 and o is correspondingly=1 or 0. Particularly preferably, m=3 and o=0.

Preferred substituents R in structures of the formula (31) or (31a) are selected, identically or differently on each occurrence, from the group consisting of H, D, F, CN, N(Ar)₂, N(R¹)₂, C(═O)Ar, a straight-chain alkyl or alkoxy group having 1 to 10 C atoms or a branched or cyclic alkyl or alkoxy group having 3 to 10 C atoms or an alkenyl group having 2 to 10 C atoms, each of which may be substituted by one or more radicals R¹, where one or more non-adjacent CH₂ groups may be replaced by R¹C═CR¹ or O and where one or more H atoms may be replaced by D or F, an aromatic or heteroaromatic ring system having 5 to 24 aromatic ring atoms, which may in each case be substituted by one or more radicals R¹, an aryloxy or heteroaryloxy group having 5 to 24 aromatic ring atoms, which may be substituted by one or more radicals R¹, or an aralkyl or heteroaralkyl group having 5 to 24 aromatic ring atoms, which may be substituted by one or more radicals R¹, where two or more adjacent substituents R may optionally form a monocyclic or polycyclic, aliphatic ring system, which may be substituted by one or more radicals R¹.

Particularly preferred substituents R in structures of the formula (31) or (31a) are selected, identically or differently on each occurrence, from the group consisting of H, F, CN, a straight-chain alkyl group having 1 to 6 C atoms or a branched or cyclic alkyl group having 3 to 6 C atoms, each of which may be substituted by one or more radicals R¹, or an aromatic or heteroaromatic ring system having 5 to 14 aromatic ring atoms, which may in each case be substituted by one or more radicals R¹, where two or more adjacent substituents R may optionally form a monocyclic or polycyclic, aliphatic ring system, which may be substituted by one or more radicals R¹.

It is preferred here for a maximum of three substituents R, particularly preferably a maximum of two substituents R, very particularly preferably a maximum of one substituent R, in the ligand L to be other than hydrogen. Especially preferably, all substituents R stand for H.

As defined above, the ligands L′ are bidentate, monoanionic ligands. Preferred ligands L′ are selected from 1,3-diketonates derived from 1,3-diketones, such as, for example, acetylacetone, benzoylacetone, 1,5-diphenylacetylacetone, dibenzoylmethane, bis(1,1,1-trifluoroacetyl)methane, 2,2,6,6-tetramethyl-3,5-heptanedione, 3-ketonates derived from 3-ketoesters, such as, for example, ethyl acetoacetate, carboxylates derived from aminocarboxylic acids, such as, for example, pyridine-2-carboxylic acid, quinoline-2-carboxylic acid, glycine, N,N-dimethylglycine, alanine, N,N-dimethylaminoalanine, and salicyliminates derived from salicylimines, such as, for example, methylsalicylimine, ethylsalicylimine, phenylsalicylimine.

Preference is furthermore given to bidentate monoanionic ligands L′ which, with the metal, form a cyclometallated five-membered ring or six-membered ring having at least one metal-carbon bond, in particular a cyclometallated five-membered ring. These are, in particular, ligands as are generally used in the area of phosphorescent metal complexes for organic electroluminescent devices, i.e. ligands of the phenylpyridine, naphthylpyridine, phenylquinoline, phenylisoquinoline, etc., type, each of which may be substituted by one or more radicals R. A multiplicity of such ligands is known to the person skilled in the art in the area of phosphorescent electroluminescent devices, and he will be able, without inventive step, to select further ligands of this type as ligand L′ for compounds of the formula (30). In general, the combination of two groups as represented by the following formulae (32) to (59) is particularly suitable for this purpose, where one group is bonded via a neutral nitrogen atom or a carbene atom and the other group is bonded via a negatively charged carbon atom or a negatively charged nitrogen atom. The ligand L′ can then be formed from the groups of the formulae (32) to (59) through these groups bonding to one another in each case at the position denoted by #. The position at which the groups coordinate to the metal is denoted by *.

The symbols used here have the same meaning as described above, and preferably a maximum of three symbols X in each group stand for N, particularly preferably a maximum of two symbols X in each group stand for N, very particularly preferably a maximum of one symbol X in each group stands for N. Especially preferably, all symbols X stand for CR.

Preferred radicals R in the above-mentioned structures of the formulae (32) to (59) which are present as substituents on X are the same substituents as described above as preferred radicals R on the ligand L.

The complexes of the formula (30) may be facial or pseudofacial, or they may be meridional or pseudomeridional.

The above-mentioned embodiments can be combined with one another as desired. The above-mentioned preferences preferably occur simultaneously.

Suitable iridium complexes of the formula Ir(L)ₘ(L′)ₒ are shown in the following table.

```
    1
    2
    3
    4
    5
    6
    7
    8
    8
  10
  11
  12
  13
  14
  15
  16
  17
  18
  19
  20
  21
  22
  23
  24
  25
  26
  27
  28
  29
  30
  31
  32
  33
  34
  35
  36
```

The above-mentioned preferred embodiments can be combined with one another as desired. In a particularly preferred embodiment of the invention, the above-mentioned preferred embodiments apply simultaneously. In particular, the preferred organic electroluminescent device thus comprises at least one of the above-mentioned preferred triazine or pyrimidine derivatives of the formula (1) or (2) or the again preferred triazine or pyrimidine derivatives and at least one of the above-mentioned preferred iridium complexes of the formula (30) or the again preferred iridium complexes.

The organic electroluminescent device according to the invention comprises between 1 and 99% by vol., preferably between 2 and 90% by vol., particularly preferably between 3 and 40% by vol., in particular between 5 and 15% by vol., of the iridium complex, based on the entire mixture comprising emitter and matrix material. Correspondingly, the mixture comprises between 99 and 1% by vol., preferably between 98 and 10% by vol., particularly preferably between 97 and 60% by vol., in particular between 95 and 85% by vol., of the triazine or pyrimidine derivative, based on the entire mixture comprising emitter and matrix material.

The organic electroluminescent device according to the invention preferably comprises a cathode, an anode and at least one emitting layer. Apart from these layers, it may also comprise further layers, for example in each case one or more hole-injection layers, hole-transport layers, hole-blocking layers, electron-transport layers, electron-injection layers, exciton-blocking layers, electron-blocking layers and/or charge-generation layers. Interlayers, which have, for example, an exciton-blocking function, may likewise be introduced between two emitting layers. However, it should be pointed out that each of these layers does not necessarily have to be present.

The organic electroluminescent device here may comprise one emitting layer, or it may comprise a plurality of emitting layers. If a plurality of emission layers are present, these preferably have in total a plurality of emission maxima between 380 nm and 750 nm, resulting overall in white emission, i.e. various emitting compounds which are able to fluoresce or phosphoresce are used in the emitting layers. A preferred embodiment are two-layer systems, where the two layers exhibit a blue and yellow emission. Systems of this type are preferred, in particular, since the emitting layer in accordance with the present invention exhibits particularly good properties in the case of yellow emission. Two-layer systems are of particular interest for lighting applications. However, the white-emitting electroluminescent devices can also be employed as backlight for displays or, with coloured filters, as displays. A further preferred embodiment are three-layer systems, where the three layers exhibit blue, yellow and red emission.

In a preferred embodiment of the invention, the organic electroluminescent device comprises at least one further matrix material apart from the triazine or pyrimidine derivative. In general, all materials which are known as triplet matrix materials in accordance with the prior art can be employed for this purpose. The triplet level of the matrix material is preferably comparable to or higher than the triplet level of the emitter. The further matrix material here can have electron-transporting properties or hole-transporting properties, or it can be a material having a large band gap which is substantially electrically inert and does not participate in charge transport or does not do so to a significant extent, as described, for example, in WO 2010/108579.

Suitable further matrix materials which can be employed together with the triazine or pyrimidine derivative in the electroluminescent device according to the invention are ketones, phosphine oxides, sulfoxides and sulfones, for example in accordance with WO 2004/013080, WO 2004/093207, WO 2006/005627 or WO 2010/006680, triarylamines, carbazole derivatives, for example CBP (N,N-biscarbazolylbiphenyl), m-CBP or the carbazole derivatives disclosed in WO 2005/039246, US 2005/0069729, JP 2004/288381, EP 1205527, WO 2008/086851 or US 2009/0134784, indolocarbazole derivatives, for example in accordance with WO 2007/063754 or WO 2008/056746, indenocarbazole derivatives, for example in accordance with WO 2010/136109 or WO 2011/000455, azacarbazoles, for example in accordance with EP 1617710, EP 1617711, EP 1731584, JP 2005/347160, bipolar matrix materials, for example in accordance with WO 2007/137725, silanes, for example in accordance with WO 2005/111172, azaboroles or boronic esters, for example in accordance with WO 2006/117052, diazasilole derivatives, for example in accordance with WO 2010/054729, diazaphosphole derivatives, for example in accordance with WO 2010/054730, triazine derivatives, for example in accordance with WO 2010/015306, WO 2007/063754 or WO 2008/056746, zinc complexes, for example in accordance with EP 652273 or WO 2009/062578, dibenzofuran derivatives, for example in accordance with WO 2009/148015, bridged carbazole derivatives, for example in accordance with US 2009/0136779, WO 2010/050778, WO 2011/042107 or WO 2011/088877 or lactams, for example in accordance with WO 2011/116865, WO 2011/137951, WO 2013/064206 or the unpublished application EP 12007040.4. Another triplet emitter which emits at shorter wavelength, for example a green- or blue-emitting iridium or platinum complex, can also be employed as further matrix material together with the triazine or pyrimidine derivative in the organic electroluminescent device. This serves as co-matrix for the iridium complex with the benzoquinoline ligand.

It is furthermore preferred for the organic electroluminescent device according to invention to comprise a further triplet emitter which emits at longer wavelength apart from the iridium complex containing the benzoquinoline ligand. The iridium complex containing the benzoquinoline ligand serves here as co-matrix for the triplet emitter having the longer-wave emission spectrum.

In a further embodiment of the invention, the organic electroluminescent device according to the invention does not comprise a separate hole-injection layer and/or hole-transport layer and/or hole-blocking layer and/or electron-transport layer, i.e. the emitting layer is directly adjacent to the hole-injection layer or the anode, and/or the emitting layer is directly adjacent to the electron-transport layer or the electron-injection layer of the cathode, as described, for example, in WO 2005/053051.

The cathode preferably comprises metals having a low work function, metal alloys or multilayered structures comprising various metals, such as, for example, alkaline-earth metals, alkali metals, main-group metals or lanthanoids (for example Ca, Ba, Mg, Al, In, Mg, Yb, Sm, etc.). Also suitable are alloys comprising an alkali metal or alkaline-earth metal and silver, for example an alloy comprising magnesium and silver. In the case of multilayered structures, further metals which have a relatively high work function, such as, for example, Ag, may also be used in addition to the said metals, in which case combinations of the metals, such as, for example, Ca/Ag or Ba/Ag, are generally used. It may also be preferred to introduce a thin interlayer of a material having a high dielectric constant between a metallic cathode and the organic semiconductor. Suitable for this purpose are, for example, alkali metal or alkaline-earth metal fluorides, but also the corresponding oxides or carbonates (for example LiF, L₂O, BaF₂, MgO, NaF, CsF, Cs₂CO₃, etc.). The layer thickness of this layer is preferably between 0.5 and 5 nm.

The anode preferably comprises materials having a high work function. The anode preferably has a work function of greater than 4.5 eV vs. vacuum. Suitable for this purpose are on the one hand metals having a high redox potential, such as, for example, Ag, Pt or Au. On the other hand, metal/metal oxide electrodes (for example Al/NiNiOx, Al/PtOx) may also be preferred. For some applications, at least one of the electrodes must be transparent or partially transparent in order either to facilitate irradiation of the organic material (O-SCs) or the coupling-out of light (OLEDs/PLEDs, O-LASERs). A preferred structure uses a transparent anode. Preferred anode materials here are conductive mixed metal oxides. Particular preference is given to indium tin oxide (ITO) or indium zinc oxide (IZO). Preference is furthermore given to conductive, doped organic materials, in particular conductive doped polymers.

All materials as are usually used in accordance with the prior art can be used in the further layers of the organic electroluminescent device according to the invention, in particular in the hole-injection and -transport layers and in the electron-injection and -transport layers. The person skilled in the art will therefore be able to employ all materials known for organic electroluminescent devices in combination with the emitting layer according to the invention without inventive step.

The device is correspondingly structured (depending on the application), provided with contacts and finally hermetically sealed, since the lifetime of such devices is drastically shortened in the presence of water and/or air.

Preference is furthermore given to an organic electroluminescent device, characterised in that one or more layers are coated by means of a sublimation process, in which the materials are vapour-deposited in vacuum sublimation units at an initial pressure of less than 10⁻⁵ mbar, preferably less than 10⁻⁶ mbar. However, it is also possible for the initial pressure to be even lower, for example less than 10⁻⁷ mbar.

Preference is likewise given to an organic electroluminescent device, characterised in that one or more layers are coated by means of the OVPD (organic vapour phase deposition) process or with the aid of carrier-gas sublimation, in which the materials are applied at a pressure of between 10⁻⁵ mbar and 1 bar. A special case of this process is the OVJP (organic vapour jet printing) process, in which the materials are applied directly through a nozzle and thus structured (for example M. S. Arnold et al., Appl. Phys. Lett. 2008, 92, 053301).

Preference is furthermore given to an organic electroluminescent device, characterised in that one or more layers are produced from solution, such as, for example, by spin coating, or by means of any desired printing process, such as, for example, screen printing, flexographic printing, offset printing, LITI (light induced thermal imaging, thermal transfer printing), inkjet printing or nozzle printing. Soluble compounds are necessary for this purpose, which are obtained, for example, through suitable substitution.

These processes are also suitable, in particular, for oligomers, dendrimers and polymers.

Also possible are hybrid processes, in which, for example, one or more layers are applied from solution and one or more further layers are applied by vapour deposition.

These processes are generally known to the person skilled in the art and can be applied by him without inventive step to organic electroluminescent devices comprising the compounds according to the invention.

The present invention therefore furthermore relates to a process for the production of an organic electroluminescent device according to the invention, characterised in that at least one layer is applied by means of a sublimation process and/or in that at least one layer is applied by means of an OVPD (organic vapour phase deposition) process or with the aid of carrier-gas sublimation and/or in that at least one layer is applied from solution, by spin coating or by means of a printing process.

The present invention again furthermore relates to a mixture comprising at least one iridium complex which contains at least one optionally substituted benzoquinoline ligand and at least one triazine or pyrimidine derivative which has a molecular weight of at least 350 g/mol, preferably at least 400 g/mol. The same preferences as indicated above for the organic electroluminescent devices apply here to the components of the mixtures according to the invention.

Formulations of the mixture is according to the invention are necessary for the processing of the mixture is according to the invention from the liquid phase. These formulations can be, for example, solutions, dispersions or emotions. It may be preferred to use mixtures of two or more solvents for this purpose. Suitable and preferred solvents are, for example, toluene, anisole, o-, m- or p-xylene, methyl benzoate, mesitylene, tetralin, veratrol, THF, methyl-THF, THP, chlorobenzene, dioxane, phenoxytoluene, in particular 3-phenoxytoluene, (−)-fenchone, 1,2,3,5-tetramethylbenzene, 1,2,4,5-tetramethylbenzene, 1-methylnaphthalene, 2-methylbenzothiazole, 2-phenoxyethanol, 2-pyrrolidinone, 3-methylanisole, 4-methylanisole, 3,4-dimethylanisole, 3,5-dimethylanisole, acetophenone, α-terpineol, benzothiazole, butyl benzoate, cumene, cyclohexanol, cyclohexanone, cyclohexylbenzene, decalin, dodecylbenzene, ethyl benzoate, indane, methyl benzoate, NMP, p-cymene, phenetol, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene glycol monobutyl ether, tripropylene glycol dimethyl ether, tetraethylene glycol dimethyl ether, 2-isopropylnaphthalene, pentylbenzene, hexylbenzene, heptylbenzene, octylbenzene, 1,1-bis(3,4-dimethylphenyl)ethane or mixtures of these solvents. The way in which such solutions can be prepared is known to the person skilled in the art and is described, for example, in WO 2002/072714, WO 2003/019694 and the literature cited therein.

The present invention therefore furthermore relates to a formulation comprising a mixture according to the invention and at least one solvent, in particular one of the above-mentioned solvents or a mixture of these solvents.

The organic electroluminescent devices according to the invention are distinguished over the prior art by a surprisingly long, excellent lifetime. This advantage is not accompanied by impairment of the other electronic properties. The organic electroluminescent devices according to the invention are therefore highly suitable not only for yellow-emitting devices, but also, in particular, for white-emitting devices.

The invention is explained in greater detail by the following examples, without wishing to restrict it thereby. The person skilled in the art will be able to carry out the invention throughout the range disclosed using the descriptions and produce further organic electroluminescent devices according to the invention without inventive step.

### EXAMPLES

### Synthesis of Iridium Complexes Having Benzoquinoline Ligands

The following syntheses are carried out, unless indicated otherwise, in dried solvents under a protective-gas atmosphere. The metal complexes are additionally handled with exclusion of light or under yellow light. The solvents and reagents can be purchased, for example, from Sigma-ALDRICH or ABCR. The respective numbers in square brackets or the numbers indicated for individual compounds relate to the CAS numbers of the compounds known from the literature.

### Example 1

### fac-Tris(benzo[h]quinolin-10-yl-κC,κN)iridium, [337526-984]

50 g (103 mmol) of sodium [bisacetylacetonatodichloro]iridate(III) [770720-50-8] and 148 g (825 mmol) of benzo(h)quinoline [230-27-3] are suspended in 600 ml of 1,2-propylene glycol and heated under reflux for 4 days, during which an orange solid precipitates out. The mixture is then cooled, and 2 l of ethanol and 400 ml of 1 N hydrochloric acid are added. The solid is filtered off with suction, washed 5× with 500 ml of a 1:1 mixture of 1 N HCl and ethanol each time and 5× with 500 ml of a 1:1 mixture of ethanol/water each time. The product is dried and extracted in a Soxhlet apparatus with chlorobenzene over 3 days. The product is then subjected to fractional sublimation at 320° C. in a high vacuum (p about 10⁻⁵ mbar), giving 32 g (44 mmol), 43%, of the product as an orange solid. Purity: >99.5% according to HPLC.

The following compounds can be prepared analogously:

| Ex. | Benzo[h]quinoline | Product | Yield |
|---|---|---|---|
| 2 | 31485-96-8 | | 44% |
| 3 | 37062-82-1 | | 41% |
| 4 | 31493-10-4 | | 37% |
| 5 | 50781-37-8 | | 39% |

### Example 6

### fac-Bis(benzo[h]quinolin-10-yl-κC,κN)(2-(3-tert-butyl-phen-1-ylpyridine-κC,κN)iridium

Preparation analogous to Example 1, using 64.8 g (100 mmol) of bis(benzo[h]quinolin-10-yl-κC,κN)(2,4-pentanedionato-κO²,κO⁴)iridium [337526-87-1] instead of sodium[bisacetylacetonatodichloro]iridate(III) and using 23.3 g (110 mmol) of 2-[4-(1,1-dimethylethyl)phenylpyridine [524713-66-4] instead of benzo(h)quinoline. The crude product which has been extracted in a Soxhlet apparatus is purified by chromatography (silica gel, dichloromethane) and subjected to fractional sublimation at 300° C. in a high vacuum (p about 10⁻⁵ mbar), giving 28.8 g (38 mmol), 38%, of the product as an orange solid. Purity: >99.5% according to HPLC.

The following compounds can be prepared analogously:

| Ex. | Ligand | Product | Yield |
|---|---|---|---|
| 7 | 15827-72-2 | | 33% |
| 8 | 26274-35-1 | | 35% |
| 9 | 3297-72-1 | | 29% |

### Production of the OLEDs

The data of various OLEDs are presented in the following examples (see Tables 1 and 2).

Glass plates coated with structured ITO (indium tin oxide) in a thickness of 50 nm form the substrates for the OLEDs. The substrates are wet-cleaned (dishwasher, detergent Merck Extran), subsequently dried by heating at 250° C. for 15 min. and treated with an oxygen plasma before coating.

The OLEDs have in principle the following layer structure: substrate/hole-injection layer (HIL)/hole-transport layer (HTL)/electron-blocking layer (EBL)/emission layer (EML)/electron-transport layer (ETL)/optional electron-injection layer (EIL) and finally a cathode. The cathode is formed by an aluminium layer with a thickness of 100 nm. The precise structure of the OLEDs is shown in Table 1. The materials required for the production of the OLEDs are shown in Table 3.

All materials are applied by thermal vapour deposition in a vacuum chamber. The emission layer here always consists of one or two matrix materials and an emitting material as dopant. The matrix material(s) is (are) admixed therewith in a certain proportion by volume by co-evaporation. An expression such as H1:YD1 (95%:5%) here means that material H1 is present in the layer in a proportion by volume of 95% and YD1 is present in the layer in a proportion of 5%. Other layers may analogously also consist of a mixture of materials.

The OLEDs are characterised by standard methods. For this purpose, the electroluminescence spectra, the current efficiency (measured in cd/A), the power efficiency (measured in Im/W) and the external quantum efficiency (EQE, measured in percent) as a function of the luminous density, calculated from current/voltage/luminous density characteristic lines (IUL characteristic lines) assuming Lambert emission characteristics, and the lifetime are determined. The electroluminescence spectra are determined at a luminous density of 1000 cd/m², and the CIE 1931 x and y colour coordinates are calculated therefrom. The expression U1000 in Table 2 denotes the voltage required for a luminous density of 1000 cd/m². CE1000 and PE1000 denote the current and power efficiency respectively which are achieved at 1000 cd/m². Finally, EQE1000 denotes the external quantum efficiency at an operating luminous density of 1000 cd/m².

The lifetime LT is defined as the time after which the luminous density has dropped from the initial luminous density of 1000 cd/m² to 500 cd/m² on operation with constant current. The actual measurement here is carried out at a current kept constant at 50 mA/cm² and thus at an initial luminous density S which is given depending on the OLED, generally higher. The time T after which the luminance has dropped to half of S is then determined. The LT indicated at an initial luminous density of 1000 cd/m² is then obtained via the following formula with the acceleration exponent 1.6, which corresponds to standard practice for determination of the lifetime of OLEDs via an accelerated measurement.

LT=T*(S/1000 cd/m²)̂1.6

The data of the various OLEDs are summarised in Table 2. The examples denoted by V are comparative examples in accordance with the prior art, while the examples denoted by E show data of OLEDs according to the invention.

Some of the examples are explained in greater detail below in order to illustrate the advantages of the compounds according to the invention. However, it should be pointed out that this only represents a selection of the data shown in Table 2.

Examples E1 to E11 show OLEDs in which emitter YD1 is mixed in accordance with the invention with in each case one matrix material H1 to H9 or ST2. All OLEDs exhibit excellent emission characteristics with a yellow colour, power efficiencies between 70 and 100 lm/W, EQEs of typically >20% and in particular excellent operating lifetimes LT50 at an initial luminance of 1000 cd/m² in the range from 200,000 to 350,000 h.

Comparative Examples V1 to V3 use the same emitter YD1, but in this case not mixed in accordance with the invention with matrix materials CH2, SK or CBP. The performance data show a significant drop compared with Examples E1-E11 according to the invention.

Comparative Examples V4 to V8 show analogously a comparison between H1 or H2 and CH2, SK and CBP, in this case as a mixture with emitter Irppy which is not in accordance with the invention. Apart from the fact that the emission data, in particular the operating lifetime with a maximum of 66,000 h, are at a significantly lower level than with YD1, the comparison of H1 or H2 on the one hand with CH2, SK and CBP on the other hand shows that the advantage of H1 or H2 (see V4 or V5 respectively) compared with the other matrix materials (see V6 to V8) is not as large as in the case of YD1 (E1, E2 vs. V1 to V3). This clearly illustrates that the advantage of the invention lies specifically in the combination of emitter YD1 with one of the matrix materials H1 to H8 and cannot be explained simply by addition of the performance advantages of the emitter or matrix materials as such.

The further examples according to the invention show further possible embodiments of the invention.

E12 and E13 also comprise a second host material besides the mixture of emitter and host material according to the invention, i.e. involve components having a mixed matrix. These likewise exhibit excellent emission data. The operating lifetime of E13, for example, is the longest obtained in the course of all examples.

In E14, the emission layer also comprises an additional red emitter RD1 besides the mixture of YD1 and H1 according to the invention. In this case, the OLED simultaneously emits yellow and red light. An emission layer of this type can be, for example, together with a further blue emission layer, very attractive for the construction of a white OLED. Very good emission data are also obtained in this case of the mixture of a matrix with two emitters.

While emitter YD1 was always used in the previous Examples E1 to E14 according to the invention, Examples E15 to E22 now show OLEDs using alternative emitters in accordance with the synthesis examples described above, mixed with H1 or H3. YD2 here corresponds to the complex from Synthesis Example 2, YD3 to the complex from Synthesis Example 3, etc.

TABLE 1
Layer structure of the OLEDs

| | HIL | HTL | EBL | EML | ETL | EIL |
|---|---|---|---|---|---|---|
| Ex. | Thickness | Thickness | Thickness | Thickness | Thickness | Thickness |
| E1 | HAT | SpMA1 | SpMA2 | H1:YD1 (90%:10%) | ST2:LiQ (50%:50%) | — |
| | 5 nm | 70 nm | 20 nm | 30 nm | 40 nm | |
| E2 | HAT | SpMA1 | SpMA2 | H2:YD1 (90%:10%) | ST2:LiQ (50%:50%) | — |
| | 5 nm | 70 nm | 20 nm | 30 nm | 40 nm | |
| E3 | HAT | SpMA1 | SpMA2 | H3:YD1 (90%:10%) | ST2:LiQ (50%:50%) | — |
| | 5 nm | 70 nm | 20 nm | 30 nm | 40 nm | |
| E4 | HAT | SpMA1 | SpMA2 | H4:YD1 (90%:10%) | ST2:LiQ (50%:50%) | — |
| | 5 nm | 70 nm | 20 nm | 30 nm | 40 nm | |
| E5 | HAT | SpMA1 | SpMA2 | H5:YD1 (90%:10%) | ST2:LiQ (50%:50%) | — |
| | 5 nm | 70 nm | 20 nm | 30 nm | 40 nm | |
| E6 | HAT | SpMA1 | SpMA2 | H6:YD1 (90%:10%) | ST2:LiQ (50%:50%) | — |
| | 5 nm | 70 nm | 20 nm | 30 nm | 40 nm | |
| E7 | HAT | SpMA1 | SpMA2 | H7:YD1 (90%:10%) | ST2:LiQ (50%:50%) | — |
| | 5 nm | 70 nm | 20 nm | 30 nm | 40 nm | |
| E8 | HAT | SpMA1 | SpMA2 | H8:YD1 (90%:10%) | ST2:LiQ (50%:50%) | — |
| | 5 nm | 70 nm | 20 nm | 30 nm | 40 nm | |
| E9 | HAT | SpMA1 | SpMA2 | H9:YD1 (90%:10%) | ST2:LiQ (50%:50%) | — |
| | 5 nm | 70 nm | 20 nm | 30 nm | 40 nm | |
| E10 | HAT | SpMA1 | SpMA2 | ST2:YD1 (90%:10%) | ST2:LiQ (50%:50%) | — |
| | 5 nm | 70 nm | 20 nm | 30 nm | 40 nm | |
| E11 | HAT | SpMA1 | SpMA2 | H1:YD1 (90%:10%) | ST2 | LiQ |
| | 5 nm | 70 nm | 20 nm | 30 nm | 40 nm | 3 nm |
| V1 | HAT | SpMA1 | SpMA2 | CH2:YD1 (90%:10%) | ST2:LiQ (50%:50%) | — |
| | 5 nm | 70 nm | 20 nm | 30 nm | 40 nm | |
| V2 | HAT | SpMA1 | SpMA2 | SK:YD1 (90%:10%) | ST2:LiQ (50%:50%) | — |
| | 5 nm | 70 nm | 20 nm | 30 nm | 40 nm | |
| V3 | HAT | SpMA1 | SpMA2 | CBP:YD1 (90%:10%) | ST2:LiQ (50%:50%) | — |
| | 5 nm | 70 nm | 20 nm | 30 nm | 40 nm | |
| V4 | HAT | SpMA1 | SpMA2 | H1:Irppy (90%:10%) | ST2:LiQ (50%:50%) | — |
| | 5 nm | 70 nm | 20 nm | 30 nm | 40 nm | |
| V5 | HAT | SpMA1 | SpMA2 | H2:Irppy (90%:10%) | ST2:LiQ (50%:50%) | — |
| | 5 nm | 70 nm | 20 nm | 30 nm | 40 nm | |
| V6 | HAT | SpMA1 | SpMA2 | CH2:Irppy (90%:10%) | ST2:LiQ (50%:50%) | — |
| | 5 nm | 70 nm | 20 nm | 30 nm | 40 nm | |
| V7 | HAT | SpMA1 | SpMA2 | SK:Irppy (90%:10%) | ST2:LiQ (50%:50%) | — |
| | 5 nm | 70 nm | 20 nm | 30 nm | 40 nm | |
| V8 | HAT | SpMA1 | SpMA2 | CBP:Irppy (90%:10%) | ST2:LiQ (50%:50%) | — |
| | 5 nm | 70 nm | 20 nm | 30 nm | 40 nm | |
| E12 | HAT | SpMA1 | SpMA2 | H1:CH1:YD1 (45%:45%:10%) | ST2:LiQ (50%:50%) | — |
| | 5 nm | 70 nm | 20 nm | 30 nm | 40 nm | |
| E13 | HAT | SpMA1 | SpMA2 | H1:CH2:YD1 (45%:45%:10%) | ST2:LiQ (50%:50%) | — |
| | 5 nm | 70 nm | 20 nm | 30 nm | 40 nm | |
| E14 | HAT | SpMA1 | SpMA2 | H1:YD1:RD1 | ST2:LiQ (50%:50%) | — |
| | 5 nm | 70 nm | 20 nm | (85%:14.8%:0.2%) | 40 nm | |
| | | | | 30 nm | | |
| E15 | HAT | SpMA1 | SpMA2 | H1:YD2 (90%:10%) | ST2:LiQ (50%:50%) | — |
| | 5 nm | 70 nm | 20 nm | 30 nm | 40 nm | |
| E16 | HAT | SpMA1 | SpMA2 | H1:YD3 (90%:10%) | ST2:LiQ (50%:50%) | — |
| | 5 nm | 70 nm | 20 nm | 30 nm | 40 nm | |
| E17 | HAT | SpMA1 | SpMA2 | H1:YD4 (90%:10%) | ST2:LiQ (50%:50%) | — |
| | 5 nm | 70 nm | 20 nm | 30 nm | 40 nm | |
| E18 | HAT | SpMA1 | SpMA2 | H1:YD5 (90%:10%) | ST2:LiQ (50%:50%) | — |
| | 5 nm | 70 nm | 20 nm | 30 nm | 40 nm | |
| E19 | HAT | SpMA1 | SpMA2 | H3:YD6 (90%:10%) | ST2:LiQ (50%:50%) | — |
| | 5 nm | 70 nm | 20 nm | 30 nm | 40 nm | |
| E20 | HAT | SpMA1 | SpMA2 | H3:YD7 (90%:10%) | ST2:LiQ (50%:50%) | — |
| | 5 nm | 70 nm | 20 nm | 30 nm | 40 nm | |
| E21 | HAT | SpMA1 | SpMA2 | H3:YD8 (90%:10%) | ST2:LiQ (50%:50%) | — |
| | 5 nm | 70 nm | 20 nm | 30 nm | 40 nm | |
| E22 | HAT | SpMA1 | SpMA2 | H3:YD9 (90%:10%) | ST2:LiQ (50%:50%) | — |
| | 5 nm | 70 nm | 20 nm | 30 nm | 40 nm | |

TABLE 2
Emission data of the OLEDs

| | U1000 | CE1000 | PE1000 | EQE 1000 | CIE x/y at | LT |
|---|---|---|---|---|---|---|
| Ex. | (V) | (cd/A) | (lm/W) | (%) | 1000 cd/m² | (h) |
| E1 | 2.87 | 79.2 | 86.7 | 22.7 | 0.44/0.55 | 340 000 |
| E2 | 3.41 | 76.7 | 70.5 | 21.9 | 0.44/0.55 | 320 000 |
| E3 | 2.91 | 80.0 | 86.7 | 23.0 | 0.44/0.55 | 300 000 |
| E4 | 3.90 | 69.4 | 56.0 | 19.5 | 0.43/0.56 | 240 000 |
| E5 | 3.05 | 75.5 | 77.7 | 21.7 | 0.44/0.55 | 270 000 |
| E6 | 3.17 | 80.7 | 80.2 | 23.2 | 0.44/0.55 | 320 000 |
| E7 | 3.02 | 78.8 | 78.1 | 22.5 | 0.44/0.55 | 280 000 |
| E8 | 2.88 | 75.6 | 82.4 | 21.7 | 0.43/0.56 | 210 000 |
| E9 | 3.02 | 77.6 | 80.7 | 22.2 | 0.44/0.55 | 280 000 |
| E10 | 2.85 | 78.1 | 86.0 | 22.3 | 0.43/0.55 | 230 000 |
| E11 | 2.56 | 79.6 | 97.7 | 23.1 | 0.45/0.55 | 270 000 |
| V1 | 2.91 | 56.3 | 60.8 | 15.1 | 0.44/0.55 | 150 000 |
| V2 | 3.14 | 55.4 | 55.4 | 16.0 | 0.44/0.55 | 45 000 |
| V3 | 5.55 | 20.7 | 11.7 | 6.0 | 0.42/0.55 | 5 300 |
| V4 | 3.32 | 47.3 | 44.9 | 13.3 | 0.35/0.61 | 42 000 |
| V5 | 3.99 | 51.7 | 41.1 | 14.7 | 0.38/0.58 | 66 000 |
| V6 | 2.97 | 43.3 | 45.9 | 12.0 | 0.34/0.62 | 26 000 |
| V7 | 3.74 | 48.2 | 40.5 | 14.2 | 0.38/0.58 | 31 000 |
| V8 | 5.92 | 24.7 | 12.2 | 7.1 | 0.30/0.61 | 5 600 |
| E12 | 2.95 | 75.1 | 80.1 | 21.5 | 0.44/0.56 | 250 000 |
| E13 | 2.81 | 69.6 | 78.0 | 20.0 | 0.44/0.55 | 400 000 |
| E14 | 3.23 | 58.3 | 56.7 | 20.7 | 0.51/0.55 | 310 000 |
| E15 | 2.92 | 80.4 | 86.5 | 22.9 | 0.45/0.54 | 280 000 |
| E16 | 2.83 | 81.1 | 90.0 | 23.1 | 0.44/0.55 | 260 000 |
| E17 | 3.14 | 38.9 | 89.0 | 20.8 | 0.58/0.42 | 220 000 |
| E18 | 2.95 | 79.4 | 84.5 | 22.6 | 0.46/0.54 | 320 000 |
| E19 | 2.96 | 77.3 | 82.0 | 21.9 | 0.44/0.55 | 190 000 |
| E20 | 2.88 | 80.8 | 87.2 | 23.1 | 0.46/0.54 | 300 000 |
| E21 | 3.09 | 43.0 | 43.7 | 22.5 | 0.56/0.43 | 340 000 |
| E22 | 3.26 | 28.6 | 27.5 | 19.7 | 0.64/0.36 | 150 000 |

```
TABLE 3
Structural formulae of the materials for the OLEDs
  HAT
  SpMA1
  SpMA2
  CBP
  ST2
  BCP
  LiQ
  H1
  H2
  H3
  H4
  H5
  H6
  H7
  H8
  H9
  CH1
  CH2
  SK
  RD1
  YD1
  Irppy
```

1-15. (canceled)

16. An organic electroluminescent device comprising a mixture of (1) an iridium complex comprising at least one optionally substituted benzoquinoline ligand and (2) a triazine or pyrimidine derivative having a molecular weight of at least 350 g/mol in the emitting layer.

17. The organic electroluminescent device of claim 16, wherein the triazine derivative is a compound of formula (1) and the pyrimidine derivative is a compound of formula (2):
wherein:
R is selected on each occurrence, identically or differently, from the group consisting of H, D, F, CN, N(Ar)₂, N(R¹)₂, C(═O)Ar, C(═O)R¹, P(═O)(Ar)₂, a straight-chain alkyl, alkoxy, or thioalkyl group having 1 to 40 C atoms, a branched or cyclic alkyl, alkoxy, or thioalkyl group having 3 to 40 C atoms, or an alkenyl or alkynyl group having 2 to 40 C atoms, each of which is optionally substituted by one or more radicals R¹, wherein one or more non-adjacent CH₂ groups are optionally replaced by R¹C═CR¹, C≡C, Si(R¹)₂, C═O, C═S, C═NR¹, P(═O)(R¹), SO, SO₂, NR¹, O, S, or CONR¹, and wherein one or more H atoms are optionally replaced by D, F, Cl, Br, I, CN, or NO₂, an aromatic or heteroaromatic ring system having 5 to 80 aromatic ring atoms, which are optionally substituted by one or more radicals R¹, an aryloxy or heteroaryloxy group having 5 to 60 aromatic ring atoms, which is optionally substituted by one or more radicals R¹, or an aralkyl or heteroaralkyl group having 5 to 60 aromatic ring atoms, which is optionally substituted by one or more radicals R¹; and wherein two or more adjacent substituents R optionally define a monocyclic or polycyclic, aliphatic, aromatic, or heteroaromatic ring system, which is optionally substituted by one or more radicals R¹; and with the proviso that at least one group R is an aromatic or heteroaromatic ring system having 5 to 80 aromatic ring atoms, which are optionally substituted by one or more radicals R¹;
R¹ is selected on each occurrence, identically or differently, from the group consisting of H, D, F, Cl, Br, I, CN, NO₂, N(Ar)₂, N(R²)₂, C(═O)Ar, C(═O)R², P(═O)(Ar)₂, a straight-chain alkyl, alkoxy, or thioalkyl group having 1 to 40 C atoms or a branched or cyclic alkyl, alkoxy, or thioalkyl group having 3 to 40 C atoms or an alkenyl or alkynyl group having 2 to 40 C atoms, each of which is optionally substituted by one or more radicals R², wherein one or more nonadjacent CH₂ groups are optionally replaced by R²C═CR², C≡C, Si(R²)₂, C═O, C═S, C═NR², P(═O)(R²), SO, SO₂, NR², O, S, or CONR² and wherein one or more H atoms are optionally replaced by D, F, Cl, Br, I, CN, or NO₂, an aromatic or heteroaromatic ring system having 5 to 60 aromatic ring atoms, which is optionally substituted by one or more radicals R², an aryloxy or heteroaryloxy group having 5 to 60 aromatic ring atoms, which is optionally substituted by one or more radicals R², or an aralkyl or heteroaralkyl group having 5 to 60 aromatic ring atoms, which is optionally substituted by one or more radicals R²; wherein two or more adjacent substituents R¹ optionally define a monocyclic or polycyclic, aliphatic, aromatic, or heteroaromatic ring system, which is optionally substituted by one or more radicals R²;
Ar is on each occurrence, identically or differently, an aromatic or heteroaromatic ring system having 5 to 30 aromatic ring atoms, which is optionally substituted by one or more non-aromatic radicals R²; wherein two radicals Ar which are bonded to the same N atom or P atom are optionally bridged to one another by a single bond or a bridge selected from the group consisting of N(R²), C(R²)₂, O, and S; and
R² is selected from the group consisting of H, D, F, CN, an aliphatic hydrocarbon radical having 1 to 20 C atoms, an aromatic or heteroaromatic ring system having 5 to 30 aromatic ring atoms, wherein one or more H atoms are optionally replaced by D, F, Cl, Br, I, or CN, and wherein two or more adjacent substituents R² optionally define a mono- or polycyclic, aliphatic, aromatic, or heteroaromatic ring system with one another.

18. The organic electroluminescent device of claim 17, wherein the aromatic or heteroaromatic ring system of R has 5 to 60 aromatic ring atoms.

19. The organic electroluminescent device of claim 17, wherein the triazine derivative is selected from the group consisting of compounds of formula (1) and the pyrimidine derivative is selected from the group consisting of compounds of formulae (2a) to (2d):
wherein:
R is, identically or differently, an aromatic or heteroaromatic ring system having 5 to 80 aromatic ring atoms, which is optionally substituted by one or more radicals R¹.

20. The organic electroluminescent device of claim 19, wherein the aromatic or heteroaromatic ring system has 5 to 30 aromatic ring atoms.

21. The organic electroluminescent device of claim 20, wherein the aromatic or heteroaromatic ring system contain no condensed aryl or heteroaryl groups in which more than two aromatic six-membered rings are condensed directly onto one another.

22. The organic electroluminescent device of claim 17, wherein R is selected from the group consisting of benzene, ortho-, meta-, and para-biphenyls, ortho-, meta-, para-, and branched terphenyls, ortho-, meta-, para-, and branched quaterphenyls, 1-, 2-, 3-, and 4-fluorenyls, 1-, 2-, 3-, and 4-spirobifluorenyls, 1- and 2-naphthyls, pyrrole, furan, thiophene, indole, benzofuran, benzothiophene, 1-, 2-, and 3-carbazoles, 1-, 2-, and 3-dibenzofurans, 1-, 2-, and 3-dibenzothiophenes, indenocarbazole, indolocarbazole, 2-, 3-, and 4-pyridines, 2-, 4-, and 5-pyrimidines, pyrazine, pyridazine, triazine, phenanthrene, triphenylene, and combinations of two or three of these groups, wherein each of these groups is substituted by one or more radicals R¹, and/or wherein at least one group R is selected from the group consisting of structures of formulae (3) to (29):
wherein:
the dashed bond is the bond to the triazine unit in formula (1) or to the pyrimidine unit in formula (2);
X is on each occurrence, identically or differently, CR¹ or N;
Y is on each occurrence, identically or differently, C(R¹)₂, NR¹, O, S, or BR¹;
n is 0 or 1, wherein when n equals 0, no group Y is bonded at this position and instead radicals R¹ are bonded to the corresponding carbon atoms.

23. The organic electroluminescent device of claim 22, wherein no more than two X per ring is N.

24. The organic electroluminescent device of claim 22, wherein one group Y is NR¹ and the other group Y is C(R¹)₂ or both groups Y are NR¹ or both groups Y are O.

25. The organic electroluminescent device of claim 22, wherein at least one group Y is NR¹ and the substituent R¹ bonded to the nitrogen atom is an aromatic or heteroaromatic ring system having 5 to 24 aromatic ring atoms, which is optionally substituted by one or more radicals R², and/or at least one group Y is C(R¹)₂ and the substituents R¹ bonded to the carbon atom are on each occurrence a linear alkyl group having 1 to 10 C atoms or a branched or cyclic alkyl group having 3 to 10 C atoms or an aromatic or heteroaromatic ring system having 5 to 24 aromatic ring atoms, which is optionally substituted by one or more radicals R², and wherein the two groups R¹ bonded to the same carbon atom optionally define a ring with one another so as to form a spiro system, which is optionally substituted by one or more radicals R².

26. The organic electroluminescent device of claim 16, wherein the iridium complex comprising at least one optionally substituted benzoquinoline ligand is a compound of formula (30):
Ir(L)ₘ(L′)ₒ (30)
wherein Ir(L)ₘ is a structure of formula (31):
wherein
R is selected on each occurrence, identically or differently, from the group consisting of H, D, F, CN, N(Ar)₂, N(R¹)₂, C(═O)Ar, C(═O)R¹, P(═O)(Ar)₂, a straight-chain alkyl, alkoxy, or thioalkyl group having 1 to 40 C atoms, a branched or cyclic alkyl, alkoxy, or thioalkyl group having 3 to 40 C atoms, or an alkenyl or alkynyl group having 2 to 40 C atoms, each of which is optionally substituted by one or more radicals R¹, wherein one or more non-adjacent Cl₂ groups are optionally replaced by R¹C═CR¹, C≡C, Si(R¹)₂, C═O, C═S, C═NR¹, P(═O)(R¹), SO, SO₂, NR¹, O, S, or CONR¹, and wherein one or more H atoms are optionally replaced by D, F, Cl, Br, I, CN, or NO₂, an aromatic or heteroaromatic ring system having 5 to 80 aromatic ring atoms, which are optionally substituted by one or more radicals R¹, an aryloxy or heteroaryloxy group having 5 to 60 aromatic ring atoms, which is optionally substituted by one or more radicals R¹, or an aralkyl or heteroaralkyl group having 5 to 60 aromatic ring atoms, which is optionally substituted by one or more radicals R¹; and wherein two or more adjacent substituents R optionally define a monocyclic or polycyclic, aliphatic or heteroaromatic ring system, which is optionally substituted by one or more radicals R¹; and with the proviso that at least one group R is an aromatic or heteroaromatic ring system having 5 to 80 aromatic ring atoms, which are optionally substituted by one or more radicals R¹;
R¹ is selected on each occurrence, identically or differently, from the group consisting of H, D, F, Cl, Br, I, CN, NO₂, N(Ar)₂, N(R²)₂, C(═O)Ar, C(═O)R², P(═O)(Ar)₂, a straight-chain alkyl, alkoxy, or thioalkyl group having 1 to 40 C atoms or a branched or cyclic alkyl, alkoxy, or thioalkyl group having 3 to 40 C atoms or an alkenyl or alkynyl group having 2 to 40 C atoms, each of which is optionally substituted by one or more radicals R², wherein one or more nonadjacent CH₂ groups are optionally replaced by R²C═CR², C≡C, Si(R²)₂, C═O, C═S, C═NR², P(═O)(R²), SO, SO₂, NR², O, S, or CONR² and wherein one or more H atoms are optionally replaced by D, F, Cl, Br, I, CN, or NO₂, an aromatic or heteroaromatic ring system having 5 to 60 aromatic ring atoms, which is optionally substituted by one or more radicals R², an aryloxy or heteroaryloxy group having 5 to 60 aromatic ring atoms, which is optionally substituted by one or more radicals R², or an aralkyl or heteroaralkyl group having 5 to 60 aromatic ring atoms, which is optionally substituted by one or more radicals R²; wherein two or more adjacent substituents R¹ optionally define a monocyclic or polycyclic, aliphatic, aromatic, or heteroaromatic ring system, which is optionally substituted by one or more radicals R²;
Ar is on each occurrence, identically or differently, an aromatic or heteroaromatic ring system having 5 to 30 aromatic ring atoms, which is optionally substituted by one or more non-aromatic radicals R²; wherein two radicals Ar which are bonded to the same N atom or P atom are optionally bridged to one another by a single bond or a bridge selected from the group consisting of N(R²), C(R²)₂, O, and S; and
R² is selected from the group consisting of H, D, F, CN, an aliphatic hydrocarbon radical having 1 to 20 C atoms, an aromatic or heteroaromatic ring system having 5 to 30 aromatic ring atoms, wherein one or more H atoms are optionally replaced by D, F, Cl, Br, I, or CN, and wherein two or more adjacent substituents R² optionally define a mono- or polycyclic, aliphatic, aromatic, or heteroaromatic ring system with one another.
L′ is, identically or differently on each occurrence, a bidentate monoanionic ligand;
m is 1, 2, or 3; and
o is 3-m.

27. The organic electroluminescent device of claim 26, wherein the unit of formula M(L)ₘ is selected from the group consisting of structures of formula (31a):

28. The organic electroluminescent device of claim 26, wherein R is selected, identically or differently on each occurrence, from the group consisting of H, F, CN, a straight-chain alkyl group having 1 to 6 C atoms or a branched or cyclic alkyl group having 3 to 6 C atoms, each of which is optionally substituted by one or more radicals R¹, or an aromatic or heteroaromatic ring system having 5 to 14 aromatic ring atoms, which is optionally substituted by one or more radicals R¹, and wherein two or more adjacent substituents R optionally define a monocyclic or polycyclic, aliphatic ring system, which is optionally substituted by one or more radicals R¹, and wherein no more than three substituents R in the ligand L are groups other than hydrogen.

29. The organic electroluminescent device of claim 26, wherein L′ is selected from the group consisting of 1,3-diketonates derived from 1,3-diketones, 3-ketonates derived from 3-ketoesters, carboxylates derived from aminocarboxylic acids, salicyliminates derived from salicylimines, and bidentate monoanionic ligands which, with the metal, define a cyclometallated five-membered ring or six-membered ring having at least one metal-carbon bond.

30. The organic electroluminescent device of claim 16, wherein the organic electroluminescent device comprises a plurality of emitting layers, resulting overall in white emission.

31. A process for producing the organic electroluminescent device of claim 30, comprising applying at least one layer via a sublimation method and/or applying at least one layer is applied via an organic vapour-phase deposition method or with the aid of carrier-gas sublimation and/or applying at least one layer from solution via spin coating or via a printing process.

32. A mixture comprising (1) at least one iridium complex comprising at least one optionally substituted benzoquinoline ligand and (2) at least one triazine or pyrimidine derivative having a molecular weight of at least 350 g/mol.

33. A formulation comprising at least one mixture of claim 32 and at least one organic solvent.
